(19) United States
(12) Patent Application Publication
(10) Pub. No.: US 2015/0276901 A1
(43) Pub. Date: Oct. 1, 2015

(54) METHOD FOR ASCERTAINING A GRADIENT CORRECTION VALUE, AND MAGNETIC RESONANCE SYSTEM OPERABLE WITH THE CORRECTED GRADIENT VOLUME

(71) Applicant: Siemens Aktiengesellschaft, Muenchen (DE)

(72) Inventors: Brett Cowan, Auckland (NZ); Peter Speier, Erlangen (DE); Alistair Young, Auckland (NZ)

(73) Assignee: Siemens Aktiengesellschaft, Muenchen (DE)

(21) Appl. No.: 14/669,300

(22) Filed: Mar. 26, 2015

(30) Foreign Application Priority Data
Mar. 27, 2014 (DE) 102014205733.7

(51) Int. Cl. G01R 33/44; G01R 33/385

(52) U.S. Cl. CPC G01R 33/443; G01R 33/385

(57) ABSTRACT

In a method for ascertaining a gradient correction value for magnetic resonance (MR) examinations with an MR apparatus, a measurement slice is selected, with the center of the measurement slice being located outside of the isocenter of the MR scanner of the MR apparatus. A radio-frequency pulse is applied simultaneously with a slice gradient. The radio-frequency pulse is switched off and a reslice gradient is applied. A measurement signal is acquired. A phase shift is determined from the measurement signal, and a gradient correction time or a gradient correction amplitude is calculated using the phase shift.

### BACKGROUND OF THE INVENTION

1. Field of the Invention

The invention relates to a method for ascertaining a gradient correction value for magnetic resonance examinations with a magnetic resonance system.

2. Description of the Prior Art

During magnetic resonance examinations the nuclear spins in an examination object are deflected (flipped) from the longitudinal direction, which is the direction of the basic magnetic field B₀, into the transverse plane with radio-frequency pulses. Applied gradients cause the overlaying of a phase and dephasing on the signal components in the transverse plane.

This effect is used, for example, in order to depict blood flowing into the image plane in a dark color. The spins outside of the image plane are excited with a 90° radio-frequency pulse and then one or more gradient(s) is/are applied. These gradients are applied for a pre-defined time at a pre-defined value and then switched off again. Consequently the spins outside of the image plane, in particularly the spins flowing into the image plane, do not generate an MR signal, or generate an MR signal that relaxes with T₁. Shortly after saturation of the spins, as this process is called, the obtainable signal is still close to zero. Because the spins in the blood produce only a low, or no, signal, the blood appears dark in the resulting MR image, compared to the rest of the surrounding tissue.

Gradients known as bipolar gradients are used with flux measurements and diffusion measurements by contrast. These have the same duration and amplitude but an opposing directions. In the case of spins that move in the time between application of the gradients this leads to a residual phase which is used either for speed encoding or signal loss.

The phase, which a gradient overlays, results as:

φ=γ·∫₀^{t}Gdt

This effect also comes into play when applying the slice selection gradient Gₛₛ and the read gradient Gᵣ. It is therefore known, after applying the slice selection gradient Gₛₛ and before applying the read gradient Gᵣ, to apply a gradient with reverse polarity. These each have half the moment, in particular the product of amplitude multiplied by time is half the size. These gradients are also called Gᵣₛ for reslice gradient and Gₚᵣ for preread-gradient.

Calculation of the effect or moments of the gradients has limitations in two respects, however. Firstly, the applied gradients induce eddies in the examination object, and these partially cancel out the effect of the gradients. Secondly, all settings on the device can be implemented only within certain tolerances, for example an adjusted current has a desired value but the actual value can differ therefrom.

The tolerances are manageable provided image data that are artefact-free are produced during Cartesian sampling of (entry of raw data into) k-space. Problems occur, however, with radial or helical sampling of k-space. With Cartesian sampling certain phase errors are the same in every case for all of the k-space rows and are also uniformly distributed among multiple k-space rows and therefore cause only a shifting of the echo maximum in k-space. This then causes a modulation of the signal phase in the image space. The image information is not shifted in the process. With helical or radial sampling the phase errors accumulate, however, and are different from one k-space point to the next k-space point. This leads to artifacts during reconstruction of image data from the raw data entered in k-space.

To avoid this, it is known to reduce the tolerances by ascertaining the gradient correction values in order to adjust the actual gradient values to the respective desired gradient values.

A method is described in Duyn et al., Simple Correction Method for k-Space Trajectory Deviations in MRI, JMR 132, p. 150-153, 1998 in which measurements are made with and without applied slice gradients at various positions outside of the isocenter of the MR scanner. The phase differences ascertained therefrom are used in the evaluation of the data records.

Moussavi et al., Correction of Gradient-Induced Phase Errors in Radial MRI, MRM 71, p. 308-312, 2014 describe a method specifically for radial k-space sampling in which the gradient correction values are ascertained using a phantom, wherein T₁-weighted radial FLASH image data sets of multiple recording parameters are varied during data acquisition. Evaluation is consequently extremely complex.

### SUMMARY OF THE INVENTION

Taking the above state of the art as a starting point, an object of the present invention is to provide a method for ascertaining gradient correction values that can be applied in-vivo and is easy to evaluate.

This object is achieved with a method of the type described above, having the following steps:
a) selecting a measurement slice, wherein the center of the measurement slice is located outside of the isocenter of the magnetic resonance scanner,
b) applying a radio-frequency pulse, and
c) simultaneously applying a slice gradient (Gₛₛ) so as to excite nuclear spins in the measurement slice,
d) switching off the radio-frequency pulse and applying a reslice gradient (Gᵣₛ),
e) acquiring a measurement signal resulting from the excited spins,
f) ascertaining a phase shift (□ₙ) from the measurement signal, and
g) calculating a gradient correction value using the phase shift.

A basis of the invention is the fact that the resulting phase is ascertained from the shift in the gradient time switching with respect to a reference NCO (numerically controlled oscillator), and a compensation is achieved in comparison therewith. This proceeds as follows.

The NCO generates a reference signal with a frequency ω₀. All phase information is based on this reference signal. When a slice at a spacing d from the isocenter is excited with a radio-frequency pulse, this is modulated by

ω_{d}=G·d

The phase of the radio-frequency pulse can be set to the value Φ_{RF} in that at time T₀ the RF envelope of the radio-frequency pulse assumes exactly the phase Φ_{RF} relative to the NCO.

The phase Φ of the excited spins, which results as an integral over all spins in the slice, is the sum of the phase Φ_{RF} of the radio-frequency pulse and phase shift Φ_{Δ} due to tolerances in the gradient duration. The phase shift Φ_{Δ} is caused by a shift in the reference time T_{NCO} with respect to the mean time of the radio-frequency pulse. This time difference dt falsifies the compensation of the gradient moment of the slice gradient Gₛₛ by the reslice gradient Gᵣₛ, since the desired values differ from the actual values.

More precisely, at time Tₚₕ the phase Φ of the excited spins is equal to the phase Φ_{RF} of the radio-frequency pulse. The time Tₚₕ is set by virtue of the zeroth moment of the reslice gradient Gᵣₛ corresponding to the residual zeroth moment of the slice gradient Gₛₛ, measured from Tₚₕ to gradient end:

M₀(Gᵣₛ)=M₀(Gₛₛ(Tₚₕ:Ende[Gₛₛ]))

This always applies and is independent of the amplitude curve of the envelope of the radio-frequency pulse, i.e. even if the time Tₚₕ does not coincide with the pulse centerpoint. This is the case if the areas under the gradient are the same.

In the case of a discrepancy between the desired and actual times or amplitudes, the zeroth moments no longer match, and a phase shift (J results.

It is important in this connection that, due to consideration of the areas, a difference in the amplitudes can also be seen as a time variation or be transmitted into this.

A gradient is a non-constant magnetic field that is superimposed on the basic magnetic field B₀. A gradient is used to make the resonance frequencies of the protons spatially-dependent.

The following variables also apply when determining the gradient correction value:

d is the spacing of a slice from the isocenter. If there is an interval dt between the reference time T_{NCO} and the mean time of the radio-frequency pulse then this results in the following change in the gradient moment:

dM=Gₛₛ·dt

Since the gradient amplitude is dependent on the position of the slice, the following results as phase shift Φ_{Δ}

φ_{Δ}=dM·d=Gₛₛ·dt·d

The time difference dt can be ascertained and used as the gradient correction value by determining the phase shift Φ_{Δ}.

Steps b) to e) can be executed twice, with the polarity of the slice gradient Gₛₛ and of the reslice gradient Gᵣₛ being reversed during the second execution. Addition of the measurement signals results in a phase shift of 2·Φ_{Δ} overall. This should be taken into account in the evaluation. Moreover, phase shifts that occur due to the inaccuracy of the determination of the phase Φ_{RF} of the radio-frequency pulse can be averaged out in this way. These inaccuracies lead to differences in the desired phase from the actual phase of the radio-frequency pulse being interpreted as the time difference dt, and this is incorrect. This is avoided by the change in polarity.

Preferably at least one further gradient G_{fc} can be applied for flux compensation after applying the reslice gradient Gᵣₛ. Gradients for flux compensation are basically known. The gradients of one gradient direction should be configured in such a way that the zeroth and also the first moment come to zero when added, i.e. are cancelled out. In other words, this avoids a residual phase ensuing due to the movement of spins. Phase inputs due to laminar flows are avoided in this way.

Alternatively or additionally, at least one slice parallel to the measuring slice can be saturated, so spins moving, and in particular flowing, in the measurement slice do not generate a signal. If spins from above and below flow into the measurement slice then a slice above and a slice below the measurement slice may also be saturated. The saturation can occur as described in the introduction with a 90° radio-frequency pulse and a subsequent gradient, also called a crusher gradient or spoiler gradient. A slice gradient must be applied at the same time as this radio-frequency pulse because it is desired for excitation to take place slice-selectively. Alternatively, the slices outside of the measuring slice may also be excited with an inversion pulse having a flip angle between 90° and 180°, wherein the flip angle is selected such that, when it reaches the measurement slice, the signal originating from these excited spins is at or close to the zero crossing.

The phase shifts and gradient correction values, or at least one gradient correction value, can be ascertained for multiple repetition times T_{R} in each case. If the steps from applying a radio-frequency pulse to reading out the measurement signal are regarded as one measuring process, then the measuring processes differ firstly in the repetition time and preferably secondly in the polarity of the gradients. The change in polarity is not obligatory, as described above. This process may be depicted using Table 1 below:

TABLE 1

| MV | T_{R} | Pol. |
|---|---|---|
| 1 | T_{R1} | + |
| 2 | T_{R1} | − |
| 3 | T_{R2} | + |
| 4 | T_{R2} | − |
| 5 | T_{R3} | + |
| 6 | T_{R3} | + |
| 7 | T_{R4} | + |
| 8 | T_{R4} | − |

The first column shows the number of the measuring process MV, the second column the indexed repetition time and column 3 the polarity Pol. of the gradients. The designations of the polarity do not imply that all gradients have the same polarity; the intention, as in the Tables below, is rather to show only the change in polarity. If the numerical value of the slice gradient Gₛₛ has a positive sign, then that of the reslice gradient Gᵣₛ is negative and that of the flux compensation gradient G_{fc} is optionally positive again. A change in the polarity in the Table means that the sign of the numerical value of the slice gradient Gₛₛ is negative, that of the reslice gradient Gᵣₛ positive and that of the flux compensation gradient G_{fc} is optionally negative again. The durations and amplitudes for which said numerical value is a measure are preferably the same from measuring process to another measuring process.

The indexed repetition times T_{R1}, T_{R2}, . . . indicate that the repetition times can differ. A higher index in Table 1 indicates a longer repetition time. The following applies:

T_{R1}<T_{R2}<T_{R3}<T_{R4}

As Table 2 shows, this sequence can also be executed with more repetitions per repetition time:

TABLE 2

| MV | T_{R} | Pol. |
|---|---|---|
| 1 | T_{R1} | + |
| 2 | T_{R1} | − |
| 3 | T_{R1} | + |
| 4 | T_{R1} | − |
| 5 | T_{R2} | + |
| 6 | T_{R2} | + |
| 7 | T_{R2} | + |
| 8 | T_{R2} | − |
| 9 | T_{R3} | + |
| 10 | T_{R3} | − |
| 11 | T_{R3} | + |
| 12 | T_{R3} | − |
| 13 | T_{R4} | + |
| 14 | T_{R4} | + |
| 15 | T_{R4} | + |
| 16 | T_{R4} | − |

Of course more than four repetition times may also be used.

At least one of the applied gradients Gₛₛ, Gᵣₛ and G_{fc} the phase shift and the gradient correction value can advantageously be ascertained for multiple durations. In this case it is not the repetition time T_{R} that is varied therefore but the duration of the gradients. To obtain the gradient moment, the gradient strength, i.e. the gradient amplitude, of the gradient(s) changed in the duration should be adjusted. Alternatively or additionally, steps b) to e) can therefore be repeated, with the gradient amplitudes of the gradients Gₛₛ, Gᵣₛ or G_{fc} being varied.

Steps b) to e) can likewise be repeated, with the pulse durations of the radio-frequency pulse being varied. The attenuation of the radio-frequency pulses should also be adjusted to obtain the same slice thickness in each case. This applies if the duration of the slice gradient Gₛₛ is to be changed. The change in the duration of the gradients Gᵣₛ and G_{fc} does not affect the slice thickness by contrast. Dependencies of the phase shifts on gradient amplitudes can be ascertained in this way. The variation in the duration of the gradients, gradient amplitudes and/or the attenuation or duration of the radio-frequency pulse therefore basically occurs independently of each other. If, however, for example the slice thickness should be maintained, additional boundary conditions result that cause dependencies as described.

Steps b) to e) can advantageously be repeated, with the polarity of the gradients Gₛₛ, Gᵣₛ and G_{fc} remaining the same with a pre-defined number of successive repetitions and being reversed with an identical number. In other words, multiple measurement processes are performed, wherein the polarity is not changed, or does not have to be changed, with each measurement process.

The pre-defined number can preferably increase. Table 3 shows one possible embodiment:

TABLE 3

| MV | Pol. |
|---|---|
| 1 | + |
| 2 | − |
| 3 | + |
| 4 | − |
| 5 | + |
| 6 | + |
| 7 | − |
| 8 | − |
| 9 | + |
| 10 | + |
| 11 | − |
| 12 | − |
| 13 | + |
| 14 | + |
| 15 | + |
| 16 | − |
| 17 | − |
| 18 | − |
| 19 | + |
| 20 | + |
| 21 | + |
| 22 | − |
| 23 | − |
| 24 | − |

It can be seen that to start with the polarity is changed after each measuring process, then after each second one, then after each third one, etc. Since the measuring processes each have a change in polarity and an averaging the number of measurement processes for each number of constant polarities is a multiple of four. In the case of measurement processes 1 to 4 the number of successive repetitions is one; the polarities change with each measuring process. A repetition is based only on changes in polarity; the repetition of the measurement process as such results from the numbering.

In the case of measuring processes 5 to 12 the number of successive repetitions is two, in the case of measurement processes 13 to 24 it is three. The number is therefore increasing, in particular increasing by one.

Table 4 shows an increasing number of successive repetitions without averaging processes:

TABLE 4

| MV | Pol. |
|---|---|
| 1 | + |
| 2 | − |
| 3 | + |
| 4 | + |
| 5 | − |
| 6 | − |
| 7 | + |
| 8 | + |
| 9 | + |
| 10 | − |
| 11 | − |
| 12 | − |

The number of measurement processes is halved as a result.

In the illustrated embodiments, starting from one, the number of repetitions increases by one in each case. This is preferred but it is also possible for the number of repetitions to be doubled.

Instead of one averaging process, a plurality of averaging processes may also be carried out.

A read gradient Gᵣ can particularly advantageously be applied during recording of the measuring signal.

In all of the described embodiments a measurement signal needs to be recorded or evaluated only once or twice, irrespective of the number of measuring processes, and, more precisely, during the last measuring processes. The long-term effects of eddies can consequently be recognized. In other words, a measuring sequence is wholly or partially simulated by the process sequence, wherein only phase shifts at a specific time are of interest and are therefore recorded and evaluated.

The gradient correction value can particularly preferably be ascertained for three orthogonal directions. The method should be carried out in three orthogonal directions for this purpose. The gradients used, in particular the slice gradient Gₛₛ the reslice-gradient Gᵣₛ and optionally the flux compensation-gradient G_{fc}, are then applied in the slice direction, in the phase direction and in the read direction. Different gradient coils respectively are used in the process, for which reason dependencies of the gradient correction value on the gradient coils are likewise taken into account.

The aforementioned is also achieved by a magnetic resonance apparatus having an MR scanner with at least one coil, at least one gradient coil, and a control computer that is configured to operate the MR scanner according to the inventive method as described above. The magnetic resonance scanner preferably has three gradient coils.

The control computer can be configured to implement the method by software or (hardwired) hardware.

### BRIEF DESCRIPTION OF THE DRAWINGS

FIG. 1 schematically illustrates a magnetic resonance apparatus.

FIG. 2 shows a first time graph for explaining the invention.

FIG. 3 shows a second time graph for explaining the invention.

FIG. 4 shows a third time graph for explaining the invention.

FIG. 5 shows a fourth time graph for explaining the invention.

FIG. 6 shows a fifth time graph for explaining the invention.

FIG. 7 shows a sequence for the acquisition of two measuring signals in accordance with the invention.

### DESCRIPTION OF THE PREFERRED EMBODIMENTS

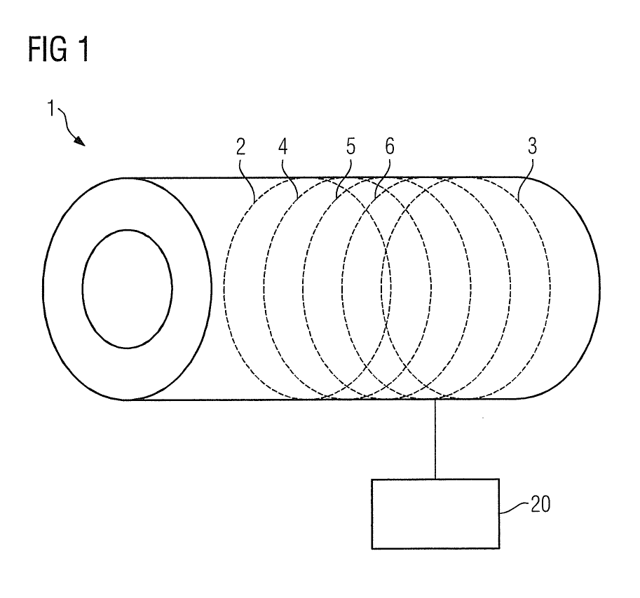

FIG. 1 shows a magnetic resonance apparatus 1 having two radio-frequency coils 2 and 3, three gradient coils 4, 5 and 6 and a controller 20 (control computer). The further elements of the magnetic resonance system 1 are not shown, for clarity.

The coil 2 is what is known as a body coil. This is used to excite the magnetization. The coil 3 is provided for reading the measurement signal. It can be designed as a coil array with multiple individual coils. The coil 3 is adapted to the examination area and implemented as what is known as a knee coil, head coil, etc. Excitation and reading of the signals is then separated. The inventive method can also be carried out with a single coil 2.

The gradient coils 4, 5 and 6 generate gradient fields that are orthogonal to each other. They can generate the gradients in the slice direction, read direction and phase encoding direction respectively. For imaging, the latter gradients can, however, also be formed by overlaying of the gradient fields of the gradient coils 4, 5 and 6.

For implementing the method it is preferred that the slice gradient Gₛₛ, reslice gradient Gᵣₛ and flux compensation gradient G_{fc} be formed by a single gradient coil, if gradient correction values are to be ascertained for a single gradient coil.

Alternatively, the slice gradient Gₛₛ, reslice gradient Gᵣₛ and flux compensation gradient G_{fc} may be formed by more than one gradient coil in order to show eddy effects in the whole sequence to be used.

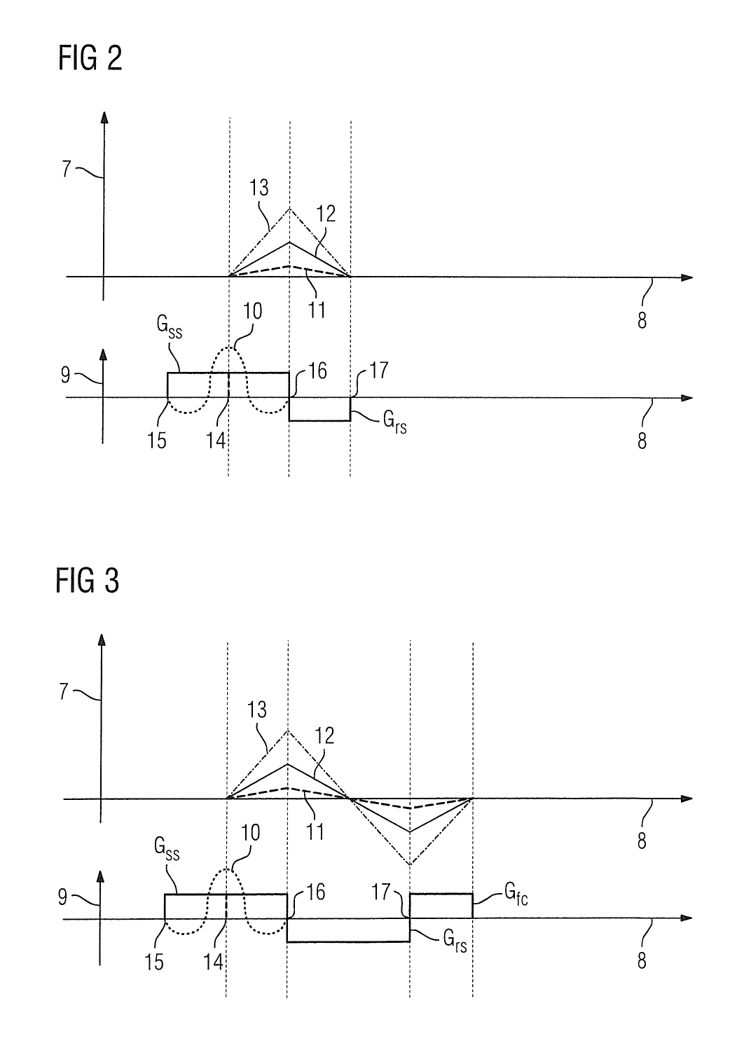

FIG. 2 shows the course over time of the phase in a slice in different planes. As described above, a gradient has the effect of changing the resonance frequencies in a specific direction as a function of location. This is achieved by a constant change in the gradient, which conventionally runs linearly. Not all spins “see” the same magnetic field strength in one slice therefore; instead location-dependent resonance frequencies result:

ω=ω₀+ω_{G(d)}=γ·(B₀+G(d))=γ·(B₀+G·d)

As described in the introduction, the phase accumulated due to the switching of the gradient G depends not only on the gradient amplitude, but also on the duration of the gradient. In a visual representation of the gradient switching the phase accordingly results as an area under the gradient. This area is also called the gradient moment M.

Plotted on axes 7 and 8 are the phase and the time respectively; the gradient amplitude is plotted on axis 9. The illustration is simplified such that there are no gradient ramps. These are obviously present in a sequence implemented on a magnetic resonance system 1 and are also easy to take into account mathematically.

The slice gradient Gₛₛ and radio-frequency pulse 10 are applied at the same time so the spins in one slice, the measuring slice, are tilted from the rest position. The slice thickness is above the gradient amplitude, i.e. the gradient strength, and the pulse profile of the radio-frequency pulse 10 is predefined.

The lines 11, 12 and 13 show the phase on the top and bottom and in the middle of the measuring slice. The side of the measuring slice facing the isocenter is designated as the bottom and the top is accordingly the side facing away from the isocenter. The gradient amplitude on the top is therefore higher, and accordingly the accumulated phase. Line 13 therefore belongs to the top, line 11 to the bottom and line 12 to the middle. Mathematically the top is given as d+Δz/2, the middle as spacing d and the bottom as d−Δz/2.

In FIG. 2 the reference time T_{NCO} and the mean time of the radio-frequency pulse 10 as well as the mean time of the slice gradient Gₛₛ match (coincide). They all occur at time 14.

The slice gradient Gₛₛ begins at time 15. It ends at time 16 and the reslice-gradient Gᵣₛ begins. The reslice-gradient Gᵣₛ ends at time 17.

The time at which the gradient moments of the slice gradient Gₛₛ and of the reslice gradient Gᵣₛ add up to zero is set as Tₚₕ. This is the time 17 in FIG. 2.

The mean time is the time in the middle between the instants 15 and 16.

The half area under the slice gradient Gₛₛ, namely the area from the time 14, causes a zeroth gradient moment M₀ in the case of stationary spins. The reslice-gradient Gᵣₛ is selected in such a way that its area matches the half area under the slice gradient Gₛₛ and due to the change in polarities generates a gradient moment −M₀. Irrespective of the course of the individual phases, which are shown by lines 11, 12 and 13, at time 17 the overlaid phase is at 0 again. This is true since the zeroth gradient moment is taken into account for stationary spins.

FIG. 3 shows a corresponding course over time in which there is also a flux compensation-gradient G_{fc} in addition to the variables described in FIG. 2.

The slice gradient Gₛₛ accordingly generates a zeroth gradient moment M₀, the reslice-gradient Gᵣₛ a zeroth gradient moment −2M₀ and the flux compensation-gradient G_{fc} a zeroth gradient moment M₀. These sum to 0. In addition, the total of the first gradient moments M₁ also balances out to 0, however.

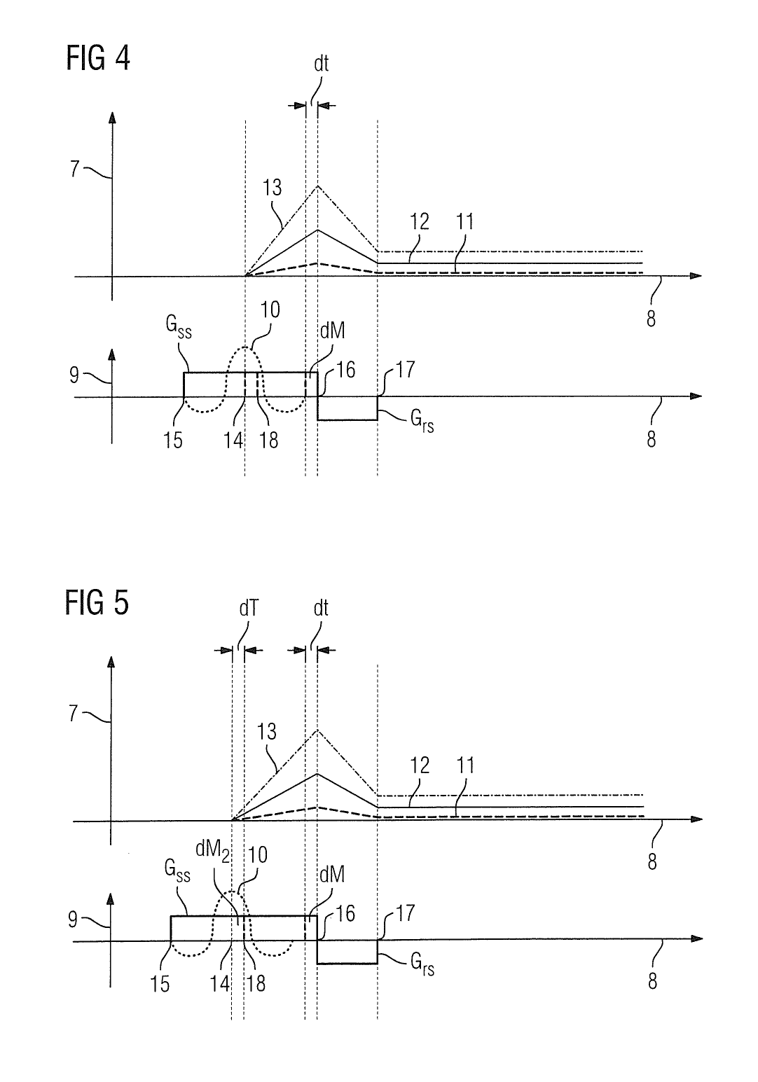

If the reference time T_{NCO} and the mean time of the radio-frequency pulse 10 are not at the same time, there is a time difference dt between these instants. FIG. 4 shows this. If the mean time is also in the middle between the instants 15 and 16, the reference time T_{NCO} is given by the time 18. The difference between the instants 14 and 18 is the time difference dt.

This produces the following change in the gradient moment:

dM=Gₛₛ·dt

Since the gradient amplitude is dependent on the position of the slice, i.e. on the spacing d of the middle of the slice from the isocenter, the following results as the phase shift Φ_{Δ}

φ_{Δ}=dM·d=Gₛₛ·dt·d

The differences within a slice shown above are taken into account using the slice gradient Gₛₛ.

The phase shift Φ_{Δ} is the sum of the phase over the whole slice.

FIG. 5 shows a further possible error mechanism when carrying out magnetic resonance experiments. If the radio-frequency pulse 10 is not symmetrical then there is a shift dT in the middle of the slice gradient Gₛₛ with respect to the middle of the radio-frequency pulse 10. This leads to a dephasing

(dM+dM₂)·Δz=BW(RF)·(dt+dT)

Here Δz denotes the slice thickness of the measuring slice, BW(RF) the bandwidth of the radio-frequency pulse 10 and dM₂ the change in gradient moment caused by the time difference dT.

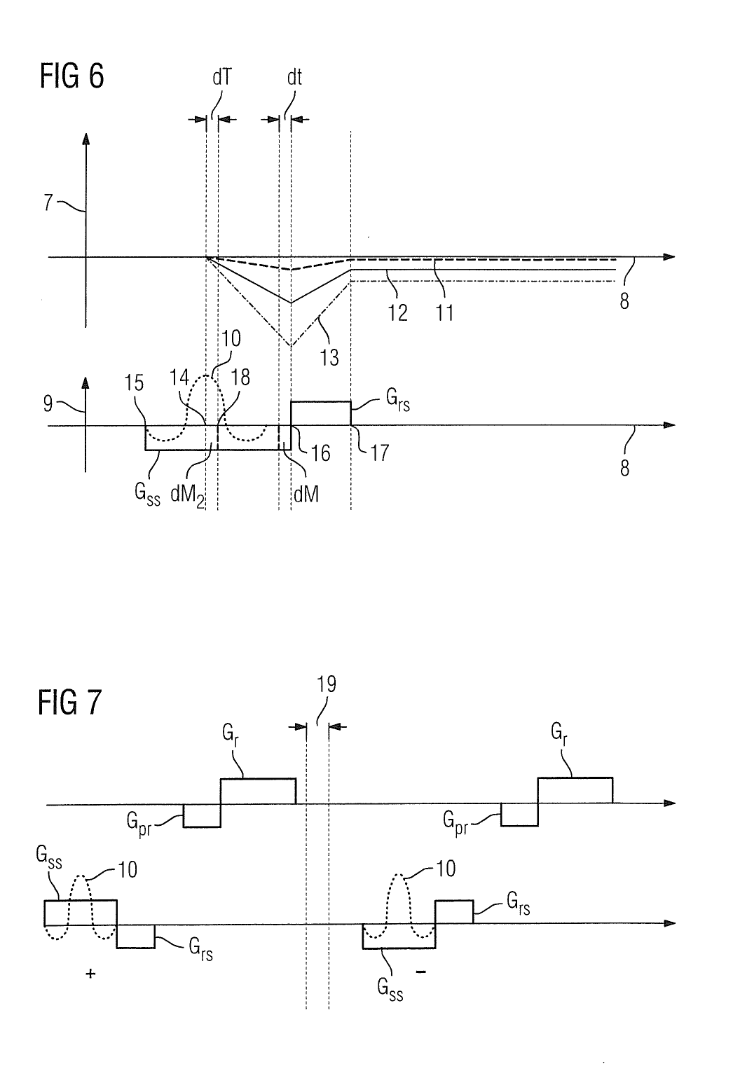

FIG. 6 shows the course over time according to FIG. 5 with a reversed polarity of gradients Gₛₛ and Gᵣₛ. If the course of the gradient according to FIG. 5 is designated by “+”, then the course according to FIG. 6 is designated by “−”. The designation could also be the other way around, however. As noted with regard to Tables 1 to 4, these symbols are intended to illustrate that the polarities of the gradients Gₛₛ, Gᵣₛ and G_{fc} are reversed. Basic statements about the value of the gradient amplitudes, the durations or other variables are not affected thereby.

FIG. 7 shows a sequence for ascertaining a phase shift Φ_{Δ}. A preread-gradient Gₚᵣ and a read gradient Gᵣ are also used in addition to the gradients Gₛₛ, Gᵣₛ and G_{fc} already shown. Signal recording takes place during application of the read gradient Gᵣ. The first section can be abbreviated to “+”, the second one to “−”. Since the respectively acquired measuring signals are added together, the resulting phase shift is given by 2·φ.

After the read gradient Gᵣ there is a delay 19 with which the repetition time T_{R} can be adjusted. Of course any other delays may be provided in the sequence.

The data acquisition pattern is given in abbreviated form by “+−”. The patterns shown in Tables 1 to 4 may be used analogously, as may the embodiments cited in relation thereto.

In general, any desired preliminary experiments may be carried out before carrying out the sequence shown in FIG. 7. By way of example, layers outside of the measuring slice may be saturated so spins flowing into the measuring slice do not make any signal contribution. Radio-frequency pulses and gradients may also be applied, however, to bring the magnetization into a steady state or generate long-term eddy effects.

In particular, at least one of the applied gradients Gₛₛ, Gᵣₛ, G_{fc} at least one phase shift Φ_{Δ} and at least one gradient correction value can be ascertained for multiple durations. The illustrated sequence can also be repeated, with the polarity of the gradients Gₛₛ, Gᵣₛ, G_{fc} remaining the same with a pre-defined number of successive repetitions and being reversed with the same number. The pre-defined number can increase. Starting from one, the number of repetitions can also increase by one in each case. FIG. 7 shows a repetition. The gradient amplitudes of the gradients Gₛₛ, Gᵣₛ, G_{fc} or the pulse durations of the radio-frequency pulse can also be varied. Dependencies of the phase shift Φ_{Δ} can be ascertained from these variables in this way.

The phase φ ascertained in this way is used to calculate a gradient correction time or a gradient correction amplitude as the gradient correction value.

The gradient correction values are particularly advantageously used to correct a spiral or radial k-space sampling pattern or a “UTE flow” sequence.

The correction is made by adding the gradient correction values to the pre-defined values, i.e. a gradient duration is shortened or lengthened and/or a gradient amplitude is reduced or increased.

Although modifications and changes may be suggested by those skilled in the art, it is the intention of the inventors to embody within the patent warranted hereon all changes and modifications as reasonably and properly come within the scope of their contribution to the art.

We claim as our invention:

1. A method for determining a gradient correction value for a magnetic (MR) examination, comprising:
(a) via a control computer of an MR scanner, making an entry that selects a measurement slice of an examination subject from which MR diagnostic data are to be acquired, with a center of said measurement slice being situated outside of an isocenter of said MR scanner;
(b) from said control computer, operating a radio-frequency (RF) coil arrangement of said MR scanner to radiate an RF pulse while said examination subject is situated in said MR scanner;
(c) simultaneously with radiating said RF pulse, operating a gradient coil system of said MR scanner from said control unit to activate a slice gradient;
(d) from said control computer, operating said RF coil arrangement to stop radiating said RF pulse and operating said gradient coil system to activate a reslice gradient;
(e) from said control computer, operating said MR scanner to acquire an MR measurement signal from said slice;
(f) in said control computer, determining a phase shift from said measurement signal;
(g) in said control computer, calculating a gradient correction selected from the group consisting of a gradient correction time and a gradient correction amplitude, using said phase shift; and
(h) from said control computer, emitting an operating sequence, that includes operation of said gradient coil system according to said gradient correction, as an electronic signal at an output of said control computer in a form for operating said MR scanner to acquire said MR diagnostic data from the examination subject.

2. A method as claimed in claim 1 comprising executing (b) through (e) twice and operating said gradient coil system, in a first execution, to activate said slice gradient with a slice gradient polarity and to activate said reslice gradient with a reslice gradient polarity, and, in a second execution, to activate said slice gradient with a slice gradient polarity that is opposite to said slice gradient polarity in said first execution and to activate said reslice gradient with a reslice gradient polarity that is opposite to the polarity of the reslice gradient in said first execution.

3. A method as claimed in claim 1 comprising, after activating said reslice gradient, operating said gradient coil system to activate at least one further gradient for flux compensation.

4. A method as claimed in claim 1 comprising radiating said RF pulse to saturate nuclear spins in a slice parallel to said measurement slice so that saturated nuclear spins from said slice parallel to said measurement slice do not generate a signal in said measurement slice.

5. A method as claimed in claim 1 comprising repeating (b) through (f) in a polarity of repetitions and calculating said gradient correction in (g) from a plurality of phase shifts respectively determined from the plurality of repetitions.

6. A method as claimed in claim 5 comprising varying a repetition time in the respective repetitions.

7. A method as claimed in claim 1 comprising repeating (b) through (e) in multiple repetitions while maintaining respective polarities of said slice gradient and said reslice gradient to be the same in a predetermined number of said repetitions, and to be reversed in an identical further number of successive repetitions.

8. A method as claimed in claim 7 comprising successively increasing said predetermined number.

9. A method as claimed in claim 8 comprising increasing said number by one for each repetition.

10. A method as claimed in claim 1 comprising repeating (b) through (e) in multiple repetitions and, in the respective repetitions, varying respective gradient amplitudes of said slice gradient and said reslice gradient.

11. A method as claimed in claim 1 comprising repeating (b) through (e) in multiple repetitions and varying a pulse duration of said RF pulse in respective repetitions.

12. A method as claimed in claim 1 comprising operating said MR scanner to acquire said measurement signal by activating a readout gradient from said gradient coil system.

13. A method as claimed in claim 1 comprising determining said gradient correction for each of three orthogonal directions.

14. A magnetic resonance (MR) apparatus comprising:
an MR scanner comprising a radio-frequency (RF) coil arrangement and a gradient coil system;
a control computer for said MR scanner, said control computer being configured to receive an entry that selects a measurement slice of an examination subject from which diagnostic MR data are to be acquired, with a center of said measurement slice being situated outside of an isocenter of said MR scanner;
said control computer being configured to operate said RF coil arrangement of said MR scanner to radiate an RF pulse while said examination subject is situated in said MR scanner;
said control computer, simultaneously with radiating said RF pulse, being configured to operate said gradient coil system of said MR scanner to activate a slice gradient;
said control computer being configured to operate said RF coil arrangement to stop radiating said RF pulse and to operate said gradient coil system to activate a reslice gradient;
said control computer being configured to operate said MR scanner to acquire an MR measurement signal from said slice;
said control computer being configured to determine a phase shift from said measurement signal;
said control computer being configured to calculate a gradient correction selected from the group consisting of a gradient correction time and a gradient correction amplitude, using said phase shift; and
said control computer being configured to operate said MR scanner to acquire said diagnostic MR data from the examination subject according to an operating sequence that includes operation of said gradient coil system according to said gradient correction.
